(19) United States
(12) Patent Application Publication
(10) Pub. No.: US 2026/0049778 A1
(43) Pub. Date: Feb. 19, 2026

(54) HEAT-TRANSFER MEMBER AND METHOD OF MANUFACTURING THE SAME

(71) Applicants: KYUSHU UNIVERSITY, NATIONAL UNIVERSITY CORPORATION, Fukuoka-shi (JP); UACJ Corporation, Tokyo (JP)

(72) Inventors: Daiki NAKAJIMA, Aichi (JP); Yasuyuki TAKATA, Fukuoka (JP); Shoji MORI, Fukuoka (JP); Shohei KUROTANI, Fukuoka (JP)

(21) Appl. No.: 19/101,277

(22) PCT Filed: Aug. 3, 2023
(86) PCT No.: PCT/JP2023/028446

§ 371 Date: Feb. 5, 2025

(30) Foreign Application Priority Data
Sep. 28, 2022 (JP) 2022-154871

(51) Int. Cl. F28F 13/18; C25D 11/12

(52) U.S. Cl. CPC F28F 13/187; C25D 11/12

(57) ABSTRACT

A heat-transfer member (1) includes: a base material (2) that is composed of an inorganic compound containing a metal or a metal element; and an oxide layer (3) that is composed of an oxide or oxides of the metal element contained in the base material (2) and is formed on the base material (2). The oxide layer (3) has a plurality of pores (31), which include: first portions (312) that have openings (311) on the surface of the heat-transfer member (1), the openings (311) having an average opening diameter of 5 nm or larger and 70 nm or smaller; and second portions (313) that have an average pore diameter larger than the average opening diameter of the first portions (312) and are continuous with the first portions (312). The average depth of the second portions (313) is 600 nm or more and 20 μm or less.

### TECHNICAL FIELD

The present invention relates to a heat-transfer member and to a method of manufacturing the same.

### BACKGROUND ART

Cooling systems, such as boiler-coolers, that utilize phase changes of a coolant may be installed in equipment that generates large amounts of heat, such as air conditioners, chillers, boilers, and heat-engine generators. In addition, in recent years, cooling systems of this type are sometimes used to cool semiconductor components and data-center electronic equipment, which have a high heat generation density.

Cooling systems that have utilized the boiling of a coolant comprise a heat-transfer member having: a heat-receiving surface configured to be capable of thermally contacting the equipment to be cooled; and a heat-dissipating surface configured to be capable of contacting the coolant. A cooling system of this type is configured such that it can efficiently cool the equipment to be cooled by causing the coolant, which has contacted the heat-dissipating surface of the heat-transfer member, to boil. In addition, a boiling heat-transfer surface, which is characterized by a surface roughness having recessed and protruding parts having a height of 10-1,000 nm densely formed on the surface on which boiling of a liquid occurs, is described, for example, in Patent Document 1 as a technique for promoting coolant boiling.

### PRIOR ART LITERATURE

### Patent Documents

### Patent Document 1

Japanese Laid-open Patent Publication 2002-228389

### SUMMARY OF THE INVENTION

### Problems to be Solved by the Invention

As described above, cooling systems that have utilized the boiling of a coolant are capable of efficiently cooling equipment to be cooled by causing coolant contacting a heat-dissipating surface of a heat-transfer member to boil. However, with regard to the boiling heat-transfer surface disclosed in Patent Document 1, the coolant becomes resistant to boiling in, for example, the situation in which the coolant is boiled repeatedly, the situation in which the boiling heat-transfer surface is immersed in the coolant for a long period, or the like, and there is a tendency for the degree of superheating of the coolant in the vicinity of the heat-dissipating surface at the onset of boiling to increase. If the coolant contacting the heat-dissipating surface becomes resistant to boiling in this way, then there is a risk that the amount of heat transferred from the heat-dissipating surface to the coolant will become small, leading to an increase in the temperature of the equipment to be cooled.

The present invention was conceived considering this background and an object of the present invention is to provide a heat-transfer member capable of maintaining coolant-boiling-promoting effects for a long period, as well as a method of manufacturing the same.

### Means for Solving the Problems

One aspect of the present invention is a heat-transfer member comprising:
a base material that is composed of an inorganic compound containing a metal or a metal element; and
an oxide layer that is composed of an oxide or oxides of the metal element contained in the base material and is formed on the base material;
wherein:
the oxide layer has a plurality of pores, which include first portions that have openings on the surface of the heat-transfer member, the openings having an average opening diameter of 5 nm or larger and 70 nm or smaller, and second portions that have an average pore diameter larger than the average opening diameter of the first portions and that are continuous with the first portions; and
the average depth of the second portions is 600 nm or more and 20 μm or less.

In addition, another aspect of the present invention is a method of manufacturing the heat-transfer member according to the above-mentioned aspect, wherein:
by performing an anodic oxidation process on the base material under first processing conditions, the oxide layer comprising the plurality of pores, which have an average opening diameter of 5 nm or larger and 70 nm or smaller, is formed on the surface of the base material; and
subsequently, by performing an anodic oxidation process on the base material under second processing conditions, which are different from the first processing conditions, and thereby growing some of the pores from among the plurality of pores, the second portions continuous with the first portions are formed.

### Effects of the Invention

The plurality of pores that include the first portions and the second portions is provided in the oxide layer of the heat-transfer member. Pores having such a shape are capable of promoting the vaporization of superheated coolant upon contact therewith, thereby generating numerous bubbles. In addition, because the first portions of the pores have openings with comparatively small opening diameters, bubbles that have grown can be quickly separated from the heat-transfer member.

In addition, by making the average opening diameter of the first portions of the pores smaller than the average pore diameter of the second portions thereof, it is possible to curtail the penetration of liquid-phase coolant into the pores. Furthermore, by setting the average depth of the second portions of the portions to the above-mentioned specific range, a sufficient amount of gas can be retained within the pores even, for example, in the situation in which the coolant is boiled repeatedly or the situation in which it is immersed in the coolant for a long period. Because the gas retained within the pores contributes to the formation of bubble nuclei when the temperature of the coolant increases, by retaining gas in the pores, the generation of bubbles from the coolant, that is, the boiling of the coolant, can be promoted. Accordingly, the heat-transfer member is capable of promoting the boiling of the coolant and causing the coolant to boil while the degree of superheating of the coolant is comparatively low, even, for example, in the situation in which the coolant is boiled repeatedly or the situation in which it is immersed in the coolant for a long period.

As a result of the foregoing, the heat-transfer member is capable of maintaining coolant-boiling-promoting effects for a long period.

In addition, by performing the anodic oxidation process in two stages in the manufacturing method according to the above-mentioned aspect, the oxide layer is formed on the surface of the base material and pores that include the first portions and the second portions are formed in the oxide layer. In this manner, by using an electrochemical method, i.e., an anodic oxidation process, pores having the above-mentioned specific shape can easily be formed.

According to the above-mentioned aspects, as described above, a heat-transfer member capable of maintaining coolant-boiling-promoting effects for a long period, as well as a method of manufacturing the same, can be provided.

### BRIEF DESCRIPTION OF THE DRAWINGS

FIG. 1 is a partial, cross-sectional view that shows the principal parts of a heat-transfer member according to an embodiment.

FIG. 2 is a partial, cross-sectional view that shows the principal parts of the heat-transfer member according to the embodiment after a first anodic oxidation process has been performed.

FIG. 3 is an oblique view of a heat-transfer member according to an experimental example.

FIG. 4 is an electron micrograph of the surface of an oxide layer of Test Sample S1 in the experimental example.

FIG. 5 is an electron micrograph of a cross section of the oxide layer of Test Sample S1 in the experimental example.

FIG. 6 is an explanatory diagram schematically illustrating an experimental apparatus used in a subcooled pool boiling test in the experimental example.

FIG. 7 is an explanatory diagram showing an example of a boiling curve in the experimental example.

### MODES FOR CARRYING OUT THE INVENTION

### (Heat-Transfer Member)

The heat-transfer member has, for example, a heat-receiving surface configured to be capable of thermally contacting the equipment to be cooled and a heat-dissipating surface configured to be capable of contacting the coolant. The base material of the heat-transfer member is constituted from an inorganic compound containing a metal or a metal element. A metal capable of forming a porous oxide film through an anodic oxidation process, such as, for example, aluminum, an aluminum alloy, titanium, or a titanium alloy, can be used as the metal constituting the base material. In addition, a metal capable of forming a porous oxide film through an anodic oxidation process, such as, for example, indium phosphide (InP), can be used as the inorganic compound constituting the base material. From the viewpoint of improving the cooling performance of the heat-transfer member and reducing material costs, the base material of the heat-transfer member is preferably any one type of metal selected from aluminum, aluminum alloys, titanium, and titanium alloys, and more preferably any one type of metal selected from aluminum and aluminum alloys.

The chemical composition of the aluminum used as the base material of the heat-transfer member is not particularly limited; for example, a 1000-series aluminum or the like can be used as the base material. In addition, the chemical composition of an aluminum alloy used as the base material of the heat-transfer member is not particularly limited; for example, a 2000-series alloy, a 3000-series alloy, a 4000-series alloy, a 5000-series alloy, a 6000-series alloy, a 7000-series alloy, or the like can be used as the base material. From the viewpoint of thermal conductivity, the base material of the heat-transfer member is preferably constituted from a 1000-series aluminum or a 6000-series alloy.

The oxide layer composed of an oxide or oxides of the metal element contained in the base material is provided on the base material. For example, if the base material is constituted from aluminum or an aluminum alloy, then the oxide layer is constituted from alumina. In addition, if the base material is constituted from titanium or a titanium alloy, then the oxide layer is constituted from titania. The oxide layer may be provided on the entire surface of the heat-transfer member or may be provided on a partial region thereof. From the viewpoint of efficiently exchanging heat with the coolant, the oxide layer is preferably provided at least on the heat-dissipating surface of the heat-transfer member.

The plurality of pores, which include the first portions that have openings at the surface of the heat-transfer member and the second portions that are continuous with the first portions, is formed in the oxide layer. In addition, the average opening diameter of the openings in the first portions is 5 nm or larger and 70 nm or smaller, and the average pore diameter of the second portions is larger than the average opening diameter of the first portions. It is noted that a pore in which the opening diameter of the pore is smaller than the pore diameter of the interior of the pore in this way may be referred to as a reentrant-type cavity.

Pores in which the average opening diameter of the first portions is 5 nm or larger curtail excessive growth of bubbles that are produced by vaporization of the coolant, and thereby the bubbles can be released from the heat-transfer member while the size of the bubbles is comparatively small. For this reason, the heat-transfer member is capable of efficiently cooling the equipment to be cooled. From the viewpoint of further enhancing these functions and effects, the average opening diameter of the first portions of the pores is preferably 10 nm or larger, more preferably 15 nm or larger, and yet more preferably 20 nm or larger.

In addition, pores in which the average opening diameter of the first portions is 70 nm or smaller are capable of curtailing the penetration of liquid-phase coolant from the exteriors of the pores into the interiors thereof. By thereby more easily retaining gas within the pores, coolant-boiling-promoting effects can be maintained for a long period. From the viewpoint of more reliably obtaining such effects, the average opening diameter of the first portions of the pores is preferably 60 nm or smaller, more preferably 50 nm or smaller, and yet more preferably 40 nm or smaller.

From the viewpoint of further enhancing the effect of promoting the separation of bubbles from the heat-transfer member and more effectively curtailing the penetration of liquid-phase coolant into the interiors of the pores, the average opening diameter of the first portions of the pores is preferably 10 nm or larger and 60 nm or smaller, more preferably 15 nm or larger and 50 nm or smaller, and yet more preferably 20 nm or larger and 40 nm or smaller.

A method of calculating the average opening diameter of the first portions described above is as follows. First, the surface of the oxide layer is observed with an electron microscope, and an electron micrograph of the surface of the oxide layer is obtained. Ten or more pores are then randomly selected from the plurality of pores present in the electron micrograph, and the circle-equivalent diameters of the openings of the individual pores, that is, the diameters of circles having an area equal to the areas of the openings, are measured. The arithmetic average value of the circle-equivalent diameters of the first portions obtained in this manner is taken as the average opening diameter of the first portions.

The average depth of the first portions of the pores is preferably 100 nm or more and 2 μm or less, more preferably 150 nm or more and 1 μm or less, and yet more preferably 200 nm or more and 500 nm or less. In this situation, it is possible to more effectively curtail the penetration of liquid-phase coolant into the interiors of the pores and to more easily direct gas within the pores to the exteriors of the pores, thereby promoting the formation of bubbles.

A method of calculating the average depth of the first portions of the pores described above is as follows. First, a cross section substantially parallel to the thickness direction of the oxide layer is exposed by a method such as fracturing the oxide layer of the heat-transfer member, cutting the heat-transfer member, or embedding the heat-transfer member in a resin, or the like, after which mechanical polishing is performed. This cross section is observed using an electron microscope, and an electron micrograph is obtained. Three or more pores are then randomly selected from the plurality of pores present in the electron micrograph, and the depths of portions having substantially similar pore diameters (that is, the lengths of portions having substantially similar pore diameters in the extension direction of the first portions) in the first portions of the individual pores are measured. The arithmetic average value of the depths of the first portions obtained in this manner is taken as the average depth of the first portions.

The second portions of the pores are continuous with the first portions and extend from the tips of the first portions toward the base material. The average pore diameter of the second portions should be larger than the average opening diameter of the first portions. The average pore diameter of the second portions is preferably 70 nm or larger and 1,000 nm or smaller. In this situation, the volumes of the second portions can be increased. As a result, the amount of gas retained in the second portions can be increased, whereby coolant-boiling-promoting effects can be maintained for a longer period. From the viewpoint of further enhancing such functions and effects, the average pore diameter of the second portions is more preferably 90 nm or larger and 800 nm or smaller, yet more preferably 100 nm or larger and 600 nm or smaller, and particularly preferably 110 nm or larger and 400 nm or smaller.

A method of calculating the average pore diameter of the second portions of the pores described above is as follows. First, a cross section substantially parallel to the thickness direction of the oxide layer is exposed by a method such as fracturing the oxide layer of the heat-transfer member, cutting the heat-transfer member, or embedding the heat-transfer member in a resin, or the like, after which mechanical polishing is performed. This cross section is observed using an electron microscope, and an electron micrograph is obtained. Four or more pores are then randomly selected from the plurality of pores present in the electron micrograph, and the pore diameters of the central portions of the second portions of the individual pores, with respect to the depth direction of the second portions of the individual pores, are measured. The arithmetic average value of the pore diameters of the second portions obtained in this manner is taken as the average pore diameter of the second portions.

The average depth of the second portions is 600 nm or more and 20 μm or less. By setting the average depth of the second portions to 600 nm or more, it is possible to make the volumes of the second portions large and thereby to retain a sufficient amount of gas within the pores. As a result, coolant-boiling-promoting effects can be maintained for a long period. From the viewpoint of further enhancing such functions and effects, the average depth of the second portions is preferably 800 nm or more and more preferably 1 μm or less.

In addition, the average depth of the second portions is preferably at least three times the average depth of the first portions. In this situation, the volumes of the second portions can be made larger, whereby the amount of gas that can be retained within the pores can be increased. As a result, coolant-boiling-promoting effects can be maintained for a longer period. It is noted that the upper limit of the ratio of the average depth of the second portions to the average depth of the first portions should be, for example, 300.

A method of calculating the average depth of the second portions of the pores described above is as follows. First, a cross section substantially parallel to the thickness direction of the oxide layer is exposed by a method such as fracturing the oxide layer of the heat-transfer member, cutting the heat-transfer member, or embedding the heat-transfer member in a resin, or the like, after which mechanical polishing is performed. This cross section is observed using an electron microscope, and an electron micrograph is obtained. Three or more pores are then randomly selected from the plurality of pores present in the electron micrograph, and the depths from the bottoms of the individual pores to the lower ends of the first portions thereof, that is, to the lower ends of the portions of the pores in which the pore diameters thereof are substantially equal to the opening diameters thereof (i.e., the lengths from the bottoms of the pores to the lower ends of the first portions) are measured. The arithmetic average value of the depths of the second portions obtained in this manner is taken as the average depth of the second portions.

In addition to the pores that include the first portions and the second portions described above, i.e., in addition to reentrant-type cavities, pores having shapes other than the specific shape described above may be formed in the oxide layer. For example, if the oxide layer is formed by a method in which a two-step anodic oxidation process is performed on the base material as described above, then secondary pores having opening diameters and depths similar to those of the first portions can be formed in the surface of the oxide layer. Such secondary pores have the effect of increasing the contact area between the oxide layer and the coolant as well as promoting bubble generation. Consequently, the cooling performance of the heat-transfer member can be further improved by providing, in the oxide layer, secondary pores that have openings at the surface of the heat-transfer member and have an average opening diameter of 5 nm or larger and 70 nm or smaller, in addition to pores having the specific shape described above.

The shape of the heat-transfer member is not particularly limited. The heat-transfer member may be configured as, for example, a heat pipe, a heat sink, a heat-exchange fin, or the like.

### (Cooling System)

A cooling system provided with the above-mentioned heat-transfer member is provided, for example, with the heat-transfer member and a coolant that contacts the oxide layer of the heat-transfer member. For example, if the heat-transfer member is a pipe, then a heat pipe serving as a cooling system can be configured by providing an oxide layer on the inner surface of the pipe and sealing a coolant or the like inside the pipe. In addition, if, for example, the heat-transfer member is a plate-shaped heat sink, then a heat-generating body, such as a semiconductor element, should be mounted on one face of the heat-transfer member, an oxide layer should be provided on the other face thereof, and the oxide layer and the coolant should be brought into contact with each other.

Hydrocarbons such as ethanol, propanol, and isopropanol; fluorine compounds such as hydrofluorocarbons (HFCs), hydrochlorofluorocarbons (HCFCs), hydrofluoroolefins (HFOs), and hydrofluoroethers (HFEs); carbon dioxide; ammonia; or the like can be used as the coolant. It is preferable to use a coolant having a boiling point lower than 100° C. as the coolant, and it is particularly preferable to use ethanol or a hydrofluoroether. By using such a coolant, it is possible to cause the coolant to boil before the temperature of the semiconductor element or electronic equipment rises excessively and a malfunction occurs, whereby a further increase in the temperature of the semiconductor device or electronic equipment can be curtailed. For this reason, a cooling system provided with a coolant having a boiling point lower than 100° C. is suitable for cooling semiconductor elements and electronic equipment.

The cooling system is preferably configured so that the degree of superheating of the coolant on the above-mentioned oxide layer when the coolant begins to boil is 20 K or lower, more preferably 18 K or lower, and yet more preferably 16 K or lower. In this situation, the coolant contacting the oxide layer boils more readily, whereby cooling of the equipment can be performed more efficiently before the temperature thereof rises excessively.

### (Heat-Transfer Member Manufacturing Method)

When manufacturing the above-mentioned heat-transfer member, an anodic oxidation process is first performed on the base material under first processing conditions to form an oxide layer having a plurality of openings having an average opening diameter of 5 nm or larger and 70 nm or smaller on the surface of the base material. Subsequently, an anodic oxidation process should be performed on the base material under second processing conditions, which differ from the first processing conditions; by growing some of the pores from among the plurality of pores, the second portions continuous with the first portions are formed. It is noted that, hereinafter, the anodic oxidation process in the first stage of the two-stage anodic oxidation process is referred to as the first anodic oxidation process, and the anodic oxidation process in the second stage thereof is referred to as the second anodic oxidation process.

In the first anodic oxidation process, the oxide layer is formed on the surface of the base material, and portions corresponding to the first portions of the above-mentioned pores are formed in the oxide layer. In the first anodic oxidation process, the oxide layer can be formed using various methods, such as a constant-voltage DC electrolytic method, a constant-current DC electrolytic method, or a pulsed electrolytic method. In the first anodic oxidation process, the oxide layer is preferably formed on the surface of the base material using a constant-voltage DC electrolytic method or a pulsed electrolytic method. In this situation, pores having the desired shape can easily be formed.

The processing conditions in the first anodic oxidation process, that is, the first processing conditions, should be set as appropriate according to the material of the base material, the electrolytic method, and the like. For example, if the oxide layer will be formed on the surface of a base material composed of aluminum or an aluminum alloy using a constant-voltage DC electrolytic method, then an acidic electrolyte solution containing an electrolyte such as sulfuric acid or phosphoric acid may be used, or an alkaline electrolyte solution containing an electrolyte such as sodium metaborate may be used. In this situation, the applied voltage can be set, for example, in a range of 10-70 V, as appropriate. In addition, the temperature of the electrolyte solution can be set, for example, in a range of 0-40° C., as appropriate.

In addition, if the oxide layer will be formed on the surface of a base material composed of aluminum or an aluminum alloy using a constant-current DC electrolytic method, then an acidic electrolyte solution containing an electrolyte such as sulfuric acid or phosphoric acid should be used, the current density should be set, for example, to 1-20 mA/cm², and the temperature of the electrolyte solution should be set, for example, to 0-40° C. In addition, if the oxide layer will be formed on the surface of a base material composed of aluminum or an aluminum alloy using a pulsed electrolytic method, then an acidic electrolyte solution containing an electrolyte such as sulfuric acid or phosphoric acid should be used, the applied voltage should be set to 10-70 V, the duty cycle should be set to 0.2-0.8, and the temperature of the electrolyte solution should be set to 0-40° C.

In addition, if the oxide layer will be formed on the surface of a base material composed of aluminum or an aluminum alloy, then an AC alumite process can also be performed using an alkaline electrolyte solution. In this situation, as the alkaline electrolyte solution, an aqueous solution can be used that contains, for example, a phosphate, such as sodium phosphate, sodium hydrogen phosphate, sodium pyrophosphate, potassium pyrophosphate, or sodium metaphosphate; an alkali metal hydroxide, such as sodium hydroxide or potassium hydroxide; a carbonate, such as sodium carbonate, sodium bicarbonate, or potassium carbonate; ammonium hydroxide; or a mixture of these as the electrolyte.

The second anodic oxidation process may be performed continuously after the first anodic oxidation process. Alternatively, it is also possible to perform another process after the first anodic oxidation process is complete, followed by performing the second anodic oxidation process. In the second anodic oxidation process, some of the pores formed in the oxide layer in the first anodic oxidation process grow, thereby forming the second portions. More specifically, at the tips of portions of the pores formed in the first anodic oxidation process, portions having larger pore diameters than those portions are formed. Thereby, the pores formed in the oxide layer in the first anodic oxidation process become the first portions of the reentrant cavities or become secondary pores, and the portions grown from the tips of the first portions in the second anodic oxidation process become the second portions. In the second anodic oxidation process, the oxide layer is preferably formed on the surface of the base material using a constant-voltage DC electrolytic method or a pulsed electrolytic method. In this situation, pores having the desired shape can easily be formed.

The processing conditions in the second anodic oxidation process, that is, the second processing conditions, should be set as appropriate according to the material of the base material, the electrolytic method, and the like. For example, if the second anodic oxidation process will be performed using a constant-voltage DC electrolytic method, then an acidic electrolyte solution containing an electrolyte such as sulfuric acid or phosphoric acid may be used, or an alkaline electrolyte solution containing an electrolyte such as sodium metaborate may be used. In this situation, the applied voltage can be set, for example, in a range of 100-300 V, as appropriate. In addition, the temperature of the electrolyte solution can be set, for example, in a range of 0-40° C., as appropriate. If the second anodic oxidation process will be performed using a constant-voltage DC electrolytic method, the voltage applied in the second processing conditions is preferably higher than the voltage applied in the first processing conditions. Thereby, the pore diameters of the portions formed in the second anodic oxidation process can be made large more reliably, thus making it easier to form the second portions.

In addition, in the second anodic oxidation process, a second porous layer can also be formed using a pulsed electrolytic method or using an AC alumite process that employs an alkaline electrolyte solution.

If the first anodic oxidation process and the second anodic oxidation process are performed continuously, then it is also possible to switch the voltage applied in the first anodic oxidation process to the voltage applied in the second anodic oxidation process; however, it is preferable to continuously change, over a certain length of time, from the voltage applied in the first anodic oxidation process to the voltage applied in the second anodic oxidation process. By gradually changing the voltage applied in the first anodic oxidation process and performing the second anodic oxidation process, it is possible to curtail uneven growth of the oxide layer caused by abrupt application of a high voltage.

### Embodiment

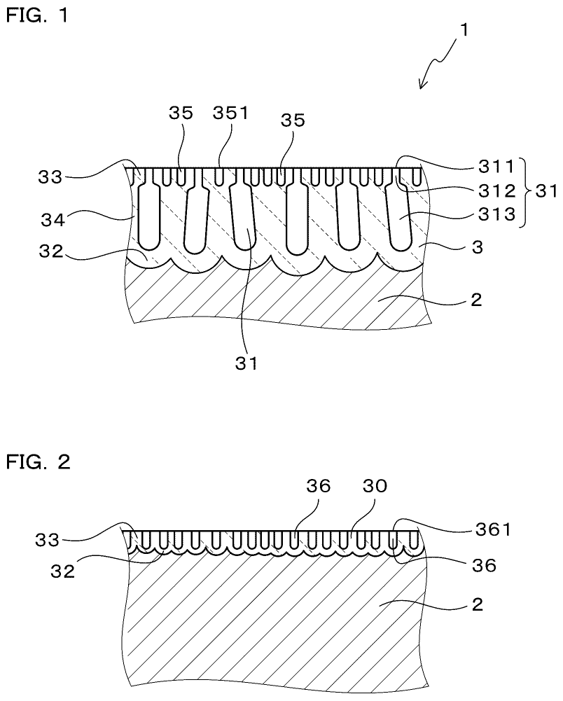

An embodiment of the heat-transfer member will be described with reference to FIG. 1 and FIG. 2. As shown in FIG. 1, a heat-transfer member 1 according to the present embodiment comprises: a base material 2 that is composed of an inorganic compound containing a metal or a metal element; and an oxide layer 3 that is composed of an oxide or oxides of the metal element contained in the base material 2 and formed on the base material 2. The oxide layer 3 has a plurality of pores 31 that include: first portions 312 that have openings 311 on the surface of the heat-transfer member 1, the openings 311 having an average opening diameter of 5 nm or larger and 70 nm or smaller; and second portions 313 that have an average pore diameter larger than the average opening diameter of the first portions 312 and are continuous with the first portions 312. In addition, the average depth of the second portions 313 of the pores 31 is 600 nm or more and 20 μm or less.

The base material 2 of the heat-transfer member 1 of the present embodiment is constituted from aluminum or an aluminum alloy. The oxide layer 3 is constituted from alumina and layered on the base material 2, and comprises: a barrier layer 32 not having the pores 31; a first porous layer 33 that is exposed on the outermost surface of the heat-transfer member 1 and has the first portions 312 of the pores 31; and a second porous layer 34 that is interposed between the barrier layer 32 and the first porous layer 33 and has the second portions 313 of the pores 31.

The first portions 312 of the pores 31 in the first porous layer 33 extend in a direction substantially parallel to the thickness direction of the oxide layer 3 and have a substantially uniform pore size throughout the entire depth direction. In addition, the first portions 312 of the pores 31 in the first porous layer 33 are continuous with any one of the second portions 313.

In addition to the first portions 312 of the pores 31, the first porous layer 33 also has a plurality of secondary pores 35 that are not continuous with the second portions 313. The secondary pores 35 have openings 351 at the surface of the heat-transfer member 1. In addition, the secondary pores 35 extend in a direction substantially parallel to the thickness direction of the oxide layer 3 and have a substantially uniform pore size throughout the entire depth direction. The average opening diameter and the average depth of the secondary pores 35 are the same as those of the first portions 312 of the pores 31.

The second portions 313 of the pores 31 in the second porous layer 34 are continuous with any one of the first portions 312 from among the first portions 312 of the pores 31 in the first porous layer 33. In addition, the second portions 313 extend in substantially parallel directions and have a substantially uniform pore size throughout the entire depth direction.

The method of manufacturing the heat-transfer member 1 of the present embodiment is, for example, as follows. First, after the base material 2 composed of aluminum or an aluminum alloy has been molded into the desired shape, the first anodic oxidation process is performed. The electrolytic method in the first anodic oxidation process is a constant-voltage DC electrolytic method or a constant-current DC electrolytic method, and the electrolyte solution is an acidic electrolyte solution containing an electrolyte such as sulfuric acid or phosphoric acid. If the first anodic oxidation process will be performed using a constant-voltage DC electrolytic method, then, for example, the applied voltage should be set to 20 V and the temperature of the electrolyte solution should be set to 0-40° C. By performing the first anodic oxidation process under such conditions, an oxide layer 30 can be formed on the base material 2, as shown in FIG. 2. The oxide layer 30 thus formed is constituted from the barrier layer 32 layered on the base material 2 and the first porous layer 33 layered on the barrier layer 32, and pores 36, which have openings 361 having an average opening diameter of 5 nm or larger and 70 nm or smaller, are formed in the first porous layer 33.

After the first anodic oxidation process has been completed, the second anodic oxidation process is performed. The electrolytic method in the second anodic oxidation process is a constant-voltage DC electrolytic method, and the electrolyte solution is an acidic electrolyte solution containing phosphoric acid as an electrolyte. In addition, in the second anodic oxidation process, the applied voltage is increased to 120 V over, for example, 2.5 minutes starting from the point in time when the first anodic oxidation process was completed, and this applied voltage is maintained. The temperature of the electrolyte solution in the second anodic oxidation process is 10° C. By performing the second anodic oxidation process under such conditions, the oxide layer 30 in FIG. 2 can be grown.

In the second anodic oxidation process, some of the pores 36, from among the pores 36 formed in the first porous layer 33, grow as the thickness of the oxide layer 30 in FIG. 2 increases, and at the tips of the portions (that is, the first portions 312) formed in the first anodic oxidation process, portions (that is, the second portions 313) having larger pore diameters than those portions are formed. Accordingly, by performing the second anodic oxidation process, the second porous layer 34 can be formed between the barrier layer 32 and the first porous layer 33, as shown in FIG. 1. In addition, those pores 36, from among the pores 36 in FIG. 2, that did not grow in the second anodic oxidation process become the secondary pores 35 in FIG. 1.

The plurality of pores 31 that include the first portions 312 and the second portions 313 is provided in the oxide layer 3 of the heat-transfer member 1 of the present embodiment. The pores 31 having such a shape are capable of promoting the vaporization of superheated coolant upon contact therewith, whereby numerous bubbles can be generated. In addition, because the first portions 312 of the pores 31 have the openings 311 with comparatively small opening diameters, bubbles that have grown can be quickly separated from the heat-transfer member 1.

In addition, because the average opening diameter of the first portions 312 of the pores 31 is smaller than the average pore diameter of the second portions 313 thereof, penetration of liquid-phase coolant into the pores 31 is curtailed. For this reason, gas is easily retained in the pores 31 of the heat-transfer member 1 even, for example, in the situation in which the coolant is boiled repeatedly or the situation in which it is immersed in the coolant for a long period. In addition, the gas within the pores 31 promotes boiling of the coolant, whereby coolant-boiling-promoting effects can be maintained for a long period.

### Experimental Examples

In the present examples, the cooling performance of heat-transfer members provided with oxide layers having various structures will be described. Note that, from among the symbols used in the experimental examples, those that are identical to the symbols used in the preceding embodiment represent constituent elements, etc., similar to the constituent elements, etc., in the preceding embodiment unless otherwise noted.

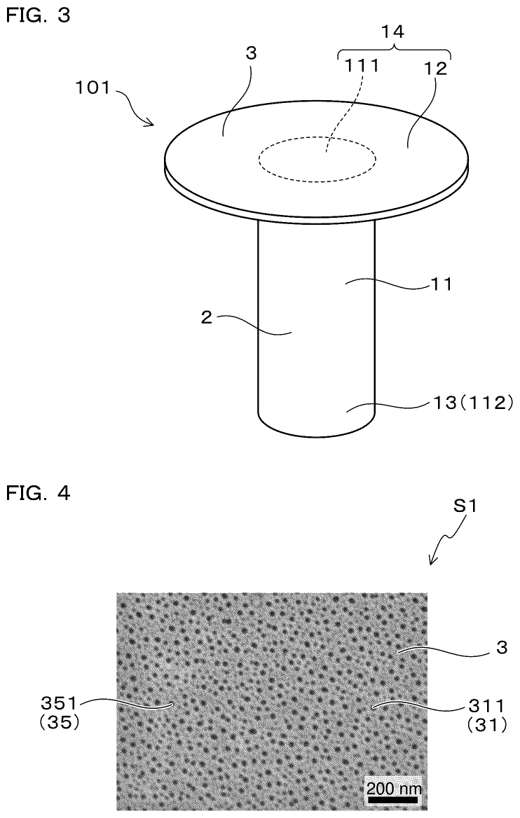

As shown in FIG. 3, a heat-transfer member 101 of the present examples includes a rod part 11 having a cylindrical shape, and a fin part 12 extending radially outward from a first end portion 111 of the rod part 11. The diameter of the rod part 11 is 30 mm and the diameter of the fin part 12 is 50 mm. A heat-receiving surface 13 of the heat-transfer member 101 is disposed at a second end portion 112 of the rod part 11, that is, the end portion on the side not having the fin part 12. A heat-dissipating surface 14 of the heat-transfer member 101 is constituted from the end surface on the side of the heat-transfer member 101 having the fin part 12, that is, the surface of the first end portion 111 of the rod part 11 and the surface of the fin part 12, and the oxide layer 3, which was provided with the pores and the secondary pores, is provided on the heat-dissipating surface 14. The base material 2 of the heat-transfer member 101 is constituted from an aluminum alloy having a chemical composition represented by the alloy number A5056.

The method of manufacturing the heat-transfer member 101 of the present examples is, for example, as follows. First, a machining process is performed on the cylindrical base material 2 to form the rod part 11 and the fin part 12. Next, the surfaces of the base material 2 other than the heat-dissipating surface 14 thereof are coated with a protective material. In this state, the first anodic oxidation process is performed using a constant-voltage DC electrolytic method. The type and concentration of the electrolyte in the electrolyte solution, the bath temperature, the applied voltage, and the length of application time in the first anodic oxidation process had the values shown in Table 1.

The second anodic oxidation process is performed consecutively after the first anodic oxidation process was completed. The electrolytic method in the second anodic oxidation process is a constant-voltage DC electrolytic method. In addition, in the second anodic oxidation process, the applied voltage is increased to the values shown in Table 1 over 2.5 minutes starting from the point in time when the first anodic oxidation process was completed, and this applied voltage is maintained. The type and concentration of the electrolyte in the electrolyte solution, the bath temperature, and the length of voltage application time in the second anodic oxidation process had the values shown in Table 1.

By the above, Test Samples S1-S3 shown in Table 1 could be obtained. The oxide layer 3 provided on the heat-dissipating surface 14 of each of Test Samples S1-S3 has the pores 31, which were provided with the first portions 312 and the second portions 313 (see FIG. 1). An electron micrograph of the surface of the oxide layer 3 of Test Sample S1 is shown in FIG. 4 as one example thereof. The portion having comparatively bright contrast in FIG. 4 is the surface of the oxide layer 3, and the portions having comparatively dark contrast are the openings 311 of the pores 31 or the openings 351 of the secondary pores 35.

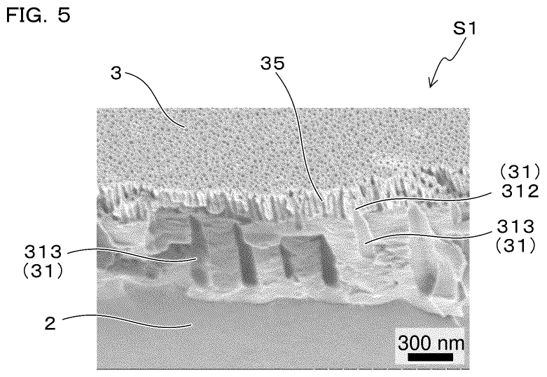

In addition, an electron micrograph of a cross section obtained by fracturing the oxide layer 3 of Test Sample S1 is shown in FIG. 5. The lower portion in FIG. 5 is the base material 2, and the fractured surface of the oxide layer 3 is exposed above the base material 2. As shown in FIG. 5, the first portions 312 of the pores 31 and the secondary pores 35, which had comparatively small pore diameters, are present in the vicinity of the surface of the oxide layer 3, and the second portions 313, which had larger pore diameters than the first portions 312, are present in the interior of the oxide layer 3.

The average opening diameters of the first portions 312, the average depths of the first portions 312, the average pore diameters of the second portions 313, and the average depths of the second portions 313 of the pores 31 in Test Samples S1-S3 are as shown in Table 2. It is noted that the average opening diameters of the first portions 312 can be calculated based on an electron micrograph of the surface of the oxide layer 3, as described above. In addition, the average depth of the first portions 312, the average pore diameter of the second portions 313, and the average depth of the second portions 313 can be calculated based on an electron micrograph of the cross section of the oxide layer 3, as described above.

In addition, Test Samples R1-R4 shown in Table 1 and Table 2 are test samples for comparison with Test Samples S1-S3. Test Samples R1-R2 have the same configuration as Test Samples S1-S3, except that the average opening diameters, etc., of the first portions 312 of the pores 31 had the values shown in Table 2. The method of manufacturing Test Samples R1-R2 is the same as the method of manufacturing Test Samples S1-S3, except that the processing conditions in the first anodic oxidation process and the second anodic oxidation process were changed as shown in Table 1.

When manufacturing Test Sample R3, after a base material similar to the base materials used to prepare Test Samples S1-S3 was prepared, the first anodic oxidation process is performed using a constant-current DC electrolytic method. The heat-transfer member thus obtained is designated Test Sample R3. The current density in the first anodic oxidation process is 5 mA/cm². In addition, the type and concentration of electrolyte, the bath temperature, and the length of current application time in the first anodic oxidation process were as shown in Table 1. It is noted that, because the applied voltage can fluctuate in a constant-voltage DC electrolytic method, the symbol “-” was recorded in the “Applied Voltage” column in Table 1. With regard to Test Sample R3, as shown in FIG. 2, the first porous layer 33 is layered over the barrier layer 32, and it does not have a second porous layer 34. The average opening diameters, etc., of the pores 36 in the first porous layer 33 of Test Sample R3 had the values shown in Table 2.

Test Sample R4 did not comprise an oxide layer 3 and is constituted from the base material 2 alone.

The cooling performance of the heat-transfer member 101 can be evaluated based on the heat transfer coefficient in a subcooled pool boiling test.

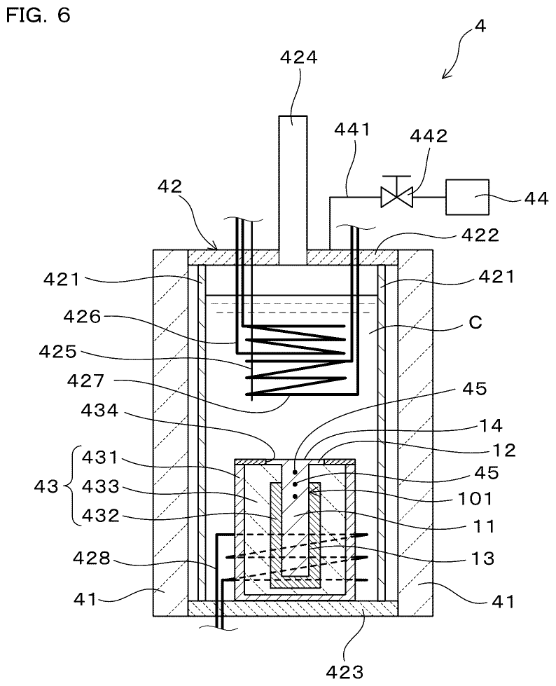

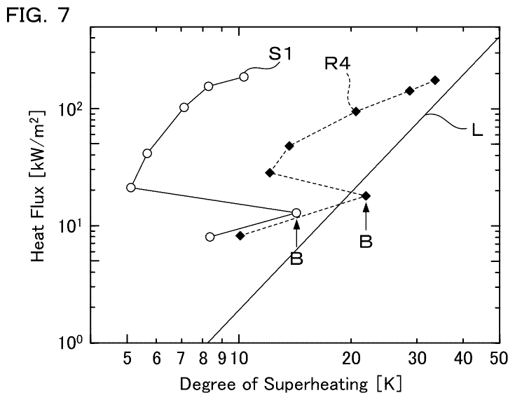

The experimental apparatus 4 used in the subcooled pool boiling test is shown in FIG. 6. The experimental apparatus 4 includes: a heat-insulating part 41, which is composed of a heat-insulating material and has a tube shape; a coolant pool 42, which was disposed within the tube of the heat-insulating part 41; a heat-source part 43, which is disposed within the coolant pool 42 and heats the heat-transfer member 101; and a vacuum pump 44 for degassing coolant C in the coolant pool 42.

The coolant pool 42 includes a sidewall part 421 disposed facing the heat-insulating part 41, a top-wall part 422 abutting the upper end of the sidewall part 421 and constituting a top surface of the coolant pool 42, and a bottom-wall portion 423 abutting the lower end of the sidewall part 421 and constituting a bottom surface of the coolant pool 42; it is configured so that coolant C could pool in the internal space surrounded by the sidewall part 421, the top-wall part 422, and the bottom-wall portion 423.

A condenser 424, a thermocouple 425, an upper-portion coolant heater 426, and a coolant cooler 427 are mounted on the top-wall part 422. The condenser 424 is configured to be capable of condensing vapor of the coolant C within the coolant pool 42 and returning the same to the interior of the coolant pool 42 as liquid-phase coolant C. The thermocouple 425 is disposed penetrating the top-wall part 422 and configured to be capable of measuring the temperature of the coolant C.

The upper-portion coolant heater 426 and the coolant cooler 427 are disposed upward of the heat-source part 43. The upper-portion coolant heater 426 and the coolant cooler 427 are connected to a temperature-adjusting apparatus not shown in the drawings, and are configured to be capable of adjusting the temperature of the coolant C by heating or cooling the coolant C.

The heat-source part 43 is disposed on the bottom-wall portion 423 of the coolant pool 42. The heat-source part 43 includes a case 431 and a heater 432, which was disposed within the case 431. The heater 432 exhibits a closed-bottomed tube shape and is configured so that the rod part 11 of the heat-transfer member 101 can be inserted thereinto. In addition, a heat-insulating material 433 is interposed between the case 431 and the heater 432. The heat-insulating material 433 is disposed to cover the rod part 11 of the heat-transfer member 101 and the heater 432. The heater 432 and the rod part 11 are thereby thermally insulated from the periphery of the heat-source part 43.

The case 431 has an opening 434 in the top surface thereof. The fin part 12 of the heat-transfer member 101 is disposed in the opening 434 in the case 431.

In addition, a lower-portion coolant heater 428 is mounted on the bottom-wall portion 423. The lower-portion coolant heater 428 is disposed around the periphery of the heat-source part 43. The lower-portion coolant heater 428, like the upper-portion coolant heater 426 and the coolant cooler 427, is connected to a temperature-adjusting apparatus not shown in the drawings, and is configured to be capable of adjusting the temperature of the coolant C by heating the coolant C.

The vacuum pump 44 is disposed on the outside of the coolant pool 42 and is connected to the coolant pool 42 via piping 441, which is attached to the top-wall part 422, and a vacuum valve 442.

Next, an experiment method for the subcooled pool boiling test will be described. First, a plurality of thermocouples 45 is mounted on the thoroughly dried rod part 11 of the heat-transfer member 101 spaced apart in the longitudinal direction of the rod part 11. These thermocouples 45 are connected to a data-processing apparatus not shown in the drawings. The data-processing apparatus is configured to be capable of calculating the temperature of the heat-dissipating surface 14 and the heat flux flowing out from the heat-dissipating surface 14 to the coolant C based on the temperature of the rod part 11 measured by the thermocouples 45.

Next, a stainless steel ring (not shown) is mounted on the outer circumference of the fin part 12. The rod part 11 of the heat-transfer member 101 is then inserted into the heater 432, and the heat-transfer member 101 is disposed so that the heat-dissipating surface 14 is exposed from the opening 434 of the case 431. Next, coolant C is poured into the coolant pool 42 until the height of the liquid level becomes 120 mm relative to the heat-dissipating surface 14. It is noted that, in the present examples, either 99.5% pure ethanol or a hydrofluoroether (“Novec® HFE-7100” manufactured by 3M) is used as the coolant C.

Next, degassing of the coolant C is performed according to the following procedure. First, the temperature of the coolant C is raised to the saturation temperature by the upper-portion coolant heater 426, the coolant cooler 427, and the lower-portion coolant heater 428. Next, the heat-transfer member 101 is heated by the heater 432, and the coolant C on the heat-dissipating surface 14 is caused to boil. After this state was held for 30 minutes, heating with the heater 432 is stopped. Subsequently, the interior of the coolant pool 42 is evacuated using the vacuum pump 44 to degas the coolant C. Then, when the temperature of the thermocouple 45, from among the plurality of thermocouples 45 mounted on the heat-transfer member 101, nearest the heat-dissipating surface 14 fell to the saturation temperature of the coolant C or lower, degassing of the coolant C was completed and the interior of the coolant pool 42 was returned to atmospheric pressure. After the interior of the coolant pool 42 had been returned to atmospheric pressure, a state in which the heat-transfer member 101 had been immersed in the coolant C for a long period is simulated by leaving it standing for 24 hours.

After preparation of the measurement was performed as described above, the temperature of the coolant C is again raised to the saturation temperature by the upper-portion coolant heater 426, the coolant cooler 427, and the lower-portion coolant heater 428. Then, two minutes after the temperature of the heat-dissipating surface 14 and the coolant C had reached a steady state, heating of the heat-transfer member 101 by the heater 432 is started and the amount of heat introduced to the heat-receiving surface 13 is gradually increased. In addition, concurrently with the start of the heating of the heat-transfer member 101, measurement of the temperature of the rod part 11 by the thermocouples 45 is started, and a boiling curve is created based on the results.

As one example, boiling curves for Test Sample S1 and Test Sample R4 when a hydrofluoroether (HFE) was used as the coolant C are shown in FIG. 7. In FIG. 7, the abscissa is the degree of superheating of the coolant C on the heat-dissipating surface 14 (i.e., the value obtained by subtracting the boiling point of the coolant C from the temperature of the heat-dissipating surface 14). In addition, the ordinate in FIG. 7 is the average value of the heat flux that flowed from the heat-dissipating surface 14 to the coolant C over 2 minutes starting from the time when the temperature of the heat-transfer member 101 and the coolant C reached a steady state. It is noted that, as described below, the points labeled “B” are points of transition from a sub-boiling state to a boiling state; thus, the temperature of the heat-transfer member 101 before and after the onset of boiling differed, and the temperature of the coolant C before and after the onset of boiling differed. Therefore, these points indicate the average heat flux value over the 30 seconds before the onset of boiling.

In experiments performed according to the method of the present examples, when the amount of heat introduced from the heat-receiving surface 13 began to increase, heat was exchanged between the heat-dissipating surface 14 and the coolant C without the coolant C on the heat-dissipating surface 14 boiling. In addition, the temperature of the coolant C on the heat-dissipating surface 14 was gradually increased by the heat introduced from the heat-receiving surface 13, whereby the coolant C entered a superheated state. Accordingly, the boiling curves from the start of the experiment until the coolant C boiled were gentle curves upward and to the right, as shown in FIG. 7.

When the temperature of the coolant C on the heat-dissipating surface 14 rose further and the degree of superheating of the coolant C reached a certain point, the coolant C began to boil. In FIG. 7, the points at which the coolant C transitioned from a sub-boiling state to a boiling state are labeled with the symbol B. After the onset of boiling, heat was removed from the heat-transfer member 101 and the temperature of the heat-dissipating surface 14 fell when the coolant C vaporized; thus, the degree of superheating of the heat-dissipating surface 14 temporarily decreased. Furthermore, because the amount of heat transferred from the heat-transfer member 101 to the coolant C increased owing to the vaporization of the coolant C, the heat flux flowing out from the heat-dissipating surface 14 to the coolant C increased. Accordingly, the boiling curves from the points at which the coolant C began to boil (i.e., the points labeled with symbol B) until a steady state was reached became curves upward and to the left, as shown in FIG. 7.

Then, when the boiling of the coolant C reached a steady state, the heat flux value increased as the degree of superheating rose. Accordingly, the boiling curves after the boiling of the coolant C reached a steady state once again became curves upward and to the right, as shown in FIG. 7. In addition, because the amount of heat transferred from the heat-transfer member to the coolant increased after boiling owing to the vaporization of the coolant, the slopes of the boiling curves after boiling became greater than the slopes of the boiling curves before boiling.

FIG. 7 shows, with a solid line L, the heat flux of nucleate boiling—as predicted based on the Rohsenow equation (equation (1) below) and assuming that the heat-dissipating surface 14 is a flat surface—for comparison with the boiling curves of the heat-transfer members 101. Note that, in equation (1) below, Cₚ is specific heat at constant volume [J·kg⁻¹·K⁻¹], ΔT is degree of superheating [K], Lₗᵥ is latent heat of evaporation [J·kg⁻¹], q is heat flux [W m⁻²], μ is absolute viscosity [Pa·s], σ is surface tension [Nm⁻¹], ρ is the density [kg·m⁻³] of the liquid-phase coolant C, ρ_{g} is the density [kg·m⁻³] of the vapor of the coolant C, and k is the thermal conductivity [W·m⁻¹·K⁻¹] of the coolant C. In addition, C_{sf} and n are parameters dependent on the combination of the coolant C and the material of the heat-transfer member 101. In the present examples, the value of C_{sf} was 0.0008 and the value of n was 1.18. These values are cited from the literature (I. L. Pioro et al. 1999).

$$\begin{matrix}[ Equation 1 ] & \\ \frac{{C}_{p} Δ T}{{L}_{lv}} = {{C}_{sf} [ \frac{q}{μ {L}_{lv}} \sqrt{\frac{σ}{g ( ρ - {ρ}_{g} )}} ]}^{0.33} {( \frac{{C}_{p} μ}{k} )}^{n} & ( 1 )\end{matrix}$$

The effects of the heat-transfer member 101 in promoting the boiling of the coolant C increases with the degree of superheating of the coolant C at the onset of boiling decreased. When the test samples and the coolants C were combined shown in Table 3, the degree of superheating of the coolant C at the onset of boiling is shown in Table 3.

TABLE 1

| | First Anodic Oxidation Process | | | | | Second Anodic Oxidation Process | | | | |
|---|---|---|---|---|---|---|---|---|---|---|
| | | | | | Appli- | | | | | Appli- |
| | Applied | | Electrolyte | Bath | cation | Applied | | Electrolyte | Bath | cation |
| Test Sample | Voltage | | Concentration | Temp. | Time | Voltage | | Concentration | Temp. | Time |
| Symbol | (V) | Electrolyte | (mol dm⁻³) | (° C.) | (min) | (V) | Electrolyte | (mol dm⁻³) | (° C.) | (min) |
| Test Sample S1 | 20 | Sulfuric acid | 0.5 | 10 | 4 | 120 | Phosphoric acid | 0.5 | 10 | 60 |
| Test Sample S2 | 20 | Sulfuric acid | 0.5 | 10 | 4 | 120 | Phosphoric acid | 0.5 | 10 | 90 |
| Test Sample S3 | 20 | Sulfuric acid | 0.5 | 10 | 4 | 120 | Phosphoric acid | 0.5 | 10 | 120 |
| Test Sample R1 | 20 | Sulfuric acid | 0.5 | 10 | 15 | 120 | Phosphoric acid | 0.5 | 10 | 30 |
| Test Sample R2 | 20 | Sulfuric acid | 0.5 | 10 | 4 | 120 | Phosphoric acid | 0.5 | 10 | 30 |
| Test Sample R3 | — | Phosphoric | 0.3 | 20 | 70 | — | — | — | — | — |
| | | acid | | | | | | | | |
| Test Sample R4 | — | — | — | — | — | — | — | — | — | — |

TABLE 2

| | First portions | | Second Portions | |
|---|---|---|---|---|
| | Average | | Average | |
| | Opening | Average | Pore | Average |
| Test Sample | Diameter | Depth | Diameter | Depth |
| Symbol | (nm) | (nm) | (nm) | (nm) |
| Test Sample S1 | 22 | 300 | 133 | 960 |
| Test Sample S2 | 23 | 360 | 173 | 1800 |
| Test Sample S3 | 30 | 360 | 170 | 2350 |
| Test Sample R1 | 10 | 3000 | 130 | 500 |
| Test Sample R2 | 10 | 300 | 90 | 500 |
| Test Sample R3 | 100 | 10000 | — | — |
| Test Sample R4 | — | — | — | — |

TABLE 3

| | | | Degree of |
|---|---|---|---|
| | | | Coolant |
| | | | Superheating |
| Experiment | Test Sample | | at Onset of |
| No. | Symbol | Coolant | Boiling (K) |
| 1 | Test Sample S1 | Ethanol | 13.4 |
| 2 | Test Sample S2 | Ethanol | 15.0 |
| 3 | Test Sample S3 | Ethanol | 12.7 |
| 4 | Test Sample S1 | HFE | 14.2 |
| 5 | Test Sample R1 | Ethanol | 22.4 |
| 6 | Test Sample R2 | Ethanol | 22.2 |
| 7 | Test Sample R3 | Ethanol | 22.7 |
| 8 | Test Sample R3 | HFE | 19.9 |
| 9 | Test Sample R4 | HFE | 22.6 |

As shown in Table 3, Test Samples S1-S3, which were provided with the pores 31 having the above-mentioned specific shape, were capable of causing the coolant C to boil at a comparatively low degree of superheating, both when ethanol was used as the coolant C and when HFE was used as the coolant C.

In contrast, the degree of superheating at the onset of boiling in Test Samples R1-R2, in which the average depth of the second portions 313 of the pores 31 was low, is higher than in Test Samples S1-S3. This is believed to be because the volume of the pores 31 in Test Samples R1-R2 is small and the amount of gas that could be retained in the pores 31 is insufficient, making it impossible to obtain the effect of promoting the boiling of the coolant C.

In addition, the degree of superheating at the onset of boiling in Test Sample R3, which did not have reentrant cavities, is higher than in Test Samples S1-S3. This is believed to be because the pore sizes of the pores 31 provided in the oxide layer 3 of Test Sample R3 are comparatively large throughout the entire lengths of the pores 31, allowing liquid-phase coolant C to easily penetrate into the pores 31 during the preparation of the test and making it impossible to retain gas in the pores 31.

In addition, the degree of superheating at the onset of boiling in Test Sample R4, which did not have pores 31, is higher than in Test Samples S1-S3. This is believed to be because no pores 31 capable of retaining gas are present on the surface of the test sample, making it impossible to obtain the effect of promoting the boiling of the coolant C.

In addition, as shown in FIG. 7, Test Sample R4, which did not have pores 31, has a boiling curve with a smaller slope after the boiling of the coolant C reached a steady state compared to Test Sample S1 and has a smaller heat flux after the coolant C boiled compared to the test samples having pores 31. Accordingly, it can be understood from a comparison of Test Sample S1 and Test Sample R4 that providing the oxide layer 3 having the pores 31 on the heat-dissipating surface 14 of the heat-transfer member 101 made it possible to markedly improve cooling performance after the coolant C boiled.

Specific aspects of the heat-transfer member 101 and the method of manufacturing the same according to the present invention have been described above based on an embodiment and experimental examples; however, the aspects of the heat-transfer member 101 and the method of manufacturing the same according to the present invention are not limited to the aspects of the embodiment and the experimental examples, and the configuration thereof can be modified, as appropriate, within a scope such that the gist of the present invention is not undermined.

For example, one aspect of the present invention is a heat-transfer member according to [1]-[5] below.
[1] A heat-transfer member comprising:
a base material that is composed of an inorganic compound containing a metal or a metal element; and
an oxide layer that is composed of an oxide or oxides of the metal element contained in the base material and is formed on the base material;
wherein:
the oxide layer has a plurality of pores, which include first portions that have openings on the surface of the heat-transfer member, the openings having an average opening diameter of 5 nm or larger and 70 nm or smaller, and second portions that have an average pore diameter larger than the average opening diameter of the first portions and that are continuous with the first portions; and
the average depth of the second portions is 600 nm or more and 20 μm or less.
[2] The heat-transfer member according to [1], wherein the average pore diameter of the second portions is 70 nm or larger and 1,000 nm or smaller.
[3] The heat-transfer member according to [1] or [2], wherein the average depth of the first portions is 100 nm or more and 2 μm or less.
[4] The heat-transfer member according to any one of [1]-[3], wherein the average depth of the second portions is at least three times the average depth of the first portions.
[5] The heat-transfer member according to any one of [1]-[4], wherein the base material is constituted from aluminum or an aluminum alloy.

In addition, another aspect of the present invention is a method of manufacturing a heat-transfer member according to [6] below.
[6] A method of manufacturing the heat-transfer member according to any one of [1]-[5], wherein:
by performing an anodic oxidation process on the base material under first processing conditions, the oxide layer comprising the plurality of pores, which have an average opening diameter of 5 nm or larger and 70 nm or smaller, is formed on the surface of the base material; and
subsequently, by performing an anodic oxidation process on the base material under second processing conditions, which are different from the first processing conditions, and thereby growing some of the pores from among the plurality of pores, the second portions continuous with the first portions are formed.

1. A heat-transfer member comprising:
a base material that is composed of an inorganic compound containing a metal or a metal element; and
an oxide layer that is composed of an oxide or oxides of the metal element contained in the base material and is formed on the base material;
wherein:
the oxide layer has a plurality of pores, which include first portions that have openings on the surface of the heat-transfer member, the openings having an average opening diameter of 5 nm or larger and 70 nm or smaller, and second portions that have an average pore diameter larger than the average opening diameter of the first portions and that are continuous with the first portions; and
the average depth of the second portions is 600 nm or more and 20 μm or less.

2. The heat-transfer member according to claim 1, wherein the average pore diameter of the second portions is 70 nm or larger and 1,000 nm or smaller.

3. The heat-transfer member according to claim 1, wherein the average depth of the first portions is 100 nm or more and 2 μm or less.

4. The heat-transfer member according to claim 1, wherein the average depth of the second portions is at least three times the average depth of the first portions.

5. The heat-transfer member according to claim 1, wherein the base material is constituted from aluminum or an aluminum alloy.

6. A method of manufacturing the heat-transfer member according to claim 1, comprising:
performing an anodic oxidation process on the base material under first processing conditions, to form an oxide layer comprising the plurality of pores, which have an average opening diameter of 5 nm or larger and 70 nm or smaller, on the surface of the base material; and
subsequently, performing an anodic oxidation process on the base material under second processing conditions, which are different from the first processing conditions, and thereby growing some of the pores from among the plurality of pores, to form the second portions continuous with the first portions.

7. The heat-transfer member according to claim 2, wherein the average depth of the first portions is 100 nm or more and 2 μm or less.

8. The heat-transfer member according to claim 7, wherein the average depth of the second portions is at least three times the average depth of the first portions.

9. The heat-transfer member according to claim 8, wherein the base material is constituted from aluminum or an aluminum alloy.

10. The heat-transfer member according to claim 8, wherein the base material is constituted from a 6000-series aluminum alloy.

11. The heat-transfer member according to claim 10, wherein the openings of the first portions have an average opening diameter of 20-40 nm.

12. The heat-transfer member according to claim 11, wherein the average depth of the first portions is 200-500 nm.

13. The heat-transfer member according to claim 12, wherein the average pore diameter of the second portions is 110-400 nm.

14. The heat-transfer member according to claim 13, wherein the average depth of the second portions is 800 nm or more and 20 μm or less.

15. A cooling system comprising:
the heat transfer member according to claim 14; and
a coolant.

16. The cooling system according to claim 15, wherein the coolant is ethanol or hydrofluoroether.

17. The cooling system according to claim 16, wherein the cooling system is configured so that the degree of superheating of the coolant on the oxide layer when the coolant begins to boil is 20 K or lower.

18. A cooling system comprising:
the heat transfer member according to claim 1; and
a coolant.

19. The cooling system according to claim 18, wherein the coolant is ethanol or hydrofluoroether.

20. The cooling system according to claim 18, wherein the cooling system is configured so that the degree of superheating of the coolant on the oxide layer when the coolant begins to boil is 20 K or lower.
